(19) United States
(12) Patent Application Publication
(10) Pub. No.: US 2026/0204302 A1
(43) Pub. Date: Jul. 16, 2026

(54) GTP Reset Circuitry and Methods

(71) Applicant: Arm Limited, Cambridge (GB)

(72) Inventors: Yattapu Viswanatha Reddy, Bangalore (IN); Georgy Jacob, Bangalore (IN); Navin Agarwal, Bangalore (IN); Tangudu Sivaramgupta, Bangalore (IN); Daksheshkumar Maganbhai Malaviya, Bangalore (IN)

(21) Appl. No.: 19/023,203

(22) Filed: Jan. 15, 2025

(51) Int. Cl. G11C 7/22

(52) U.S. Cl. CPC G11C 7/22

(57) ABSTRACT

A circuit for selective write pulse extension including: a first circuit path comprising: a delay element; a second circuit path; and a multiplexer configured to select between respective first and second global timing pulse (GTP) signals of the first circuit path and the second circuit path based on a control signal. A method for selective write pulse extension including detecting, by a circuit, one GTP pulse of a first operation mode or two GTP pulses of a second operation mode per unit cycle, where: the one GTP pulse corresponds to either a read operation or a write operation, and the two GTP pulses correspond to both the read operation and the write operation. Also, in response to the detection of the write operation as the one GTP pulse, at a reset edge of a self-timed path signal, extending a reset pulse width of the self-timed path signal.

### I. FIELD

The present disclosure is generally related to systems, methods, and devices for global timing pulse (GTP) reset delay and control circuitry.

### II. DESCRIPTION OF RELATED ART

Eviction and Allocation (EVA) represents a significant advancement in memory access optimization, particularly for CPU operations, by enabling both read and write operations within a single clock cycle at the same address. In certain cases, this architecture improves upon traditional memory access methods by leveraging dual internal Global Timing Pulses (GTPs) per external clock cycle: the first pulse handles read operations, while the second facilitates writes. The sequential organization ensures data integrity and maximizes throughput.

### III. BRIEF DESCRIPTION OF THE DRAWINGS

The present technique(s) will be described further, by way of example, with reference to embodiments thereof as illustrated in the accompanying drawings. It should be understood, however, that the accompanying drawings illustrate only the various implementations described herein and are not meant to limit the scope of various techniques, methods, systems, circuits or apparatuses described herein.

FIG. 1 is a diagram of an example circuit in accordance with various implementations described herein.

FIG. 2A is a timing diagram graph set in accordance with various implementations described herein.

FIG. 2B is a timing diagram graph set in accordance with various implementations described herein.

FIG. 3 is an operational flow diagram in accordance with various implementations described herein.

FIG. 4 is an operational method in accordance with various implementations described herein.

FIG. 5 is an operational method in accordance with various implementations described herein.

FIG. 6 is a block diagram in accordance with various implementations described herein.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### IV. DETAILED DESCRIPTION

Implementations of the present disclosure are described below with reference to the drawings. In the description, common features are designated by common reference numbers throughout the drawings.

In one implementation, the present disclosure describes a circuit for selective write pulse extension. The circuit has a first circuit path including: a delay element; a second circuit path; and a multiplexer configured to select between respective first and second global timing pulse (GTP) signals of the first circuit path and the second circuit path based on a control signal.

In another implementation, the present disclosure describes a method for selective write pulse extension. The method includes detecting, by a circuit, one GTP pulse of a first operation mode or two GTP pulses of a second operation mode per unit cycle, where: the one GTP pulse corresponds to either a read operation or a write operation, and the two GTP pulses correspond to both the read operation and the write operation. Also, in response to the detection of the write operation as the one GTP pulse, at a reset edge of a self-timed path signal, extending a reset pulse width of the self-timed path signal.

In another implementation, the present disclosure describes a method for selective write pulse extension. The method includes adjusting a GTP pulse width based on an eviction-and-allocation (EVA) control signal, where the GTP pulse width is adjusted based on a selection, by a GTP reset circuitry, of a first circuit path, and where the first circuit path corresponds to a greater propagation delay duration of a self-timed pulse (STP) in comparison to a second circuit path.

Modern memory and processing unit systems, such as CPUs, GPUs, and NPUs, face increasingly stringent timing constraints as clock frequencies continue to increase, requiring operations to be completed within progressively narrower timing windows. To address this, dual-operation modes that enable read and write operations within a single clock cycle can be implemented. This is accomplished by leveraging early write techniques, where the write operation begins before the read operation fully completes, creating sufficient timing margins for reliable operation within the clock period.

In single-operation modes, however, where a write occurs in a specific clock cycle, early write cannot be utilized. Write operations in this mode begin only after the arrival of the clock signal, leaving the timing margin constrained by the self-timed path (STP) signal, which often “shuts off too early.” This limited pulse width can lead to unsuccessful write operations, particularly as frequency targets continue to rise. The issue is further exacerbated when the same circuit configuration is used for both EVA=0 and EVA=1 modes, which fails to address the unique timing needs of EVA=0.

As would be appreciated, EVA operates in two functional modes, EVA0 (i.e., EVA=0) and EVA1 (i.e., EVA=1), each with distinct timing characteristics. EVA1 employs an early write technique that preloads data onto bit lines (BLs) prior to the write operation, reducing the required Global Timing Pulse (GTP) width and enhancing timing efficiency. This optimization enables seamless execution of both read and write operations within a single clock cycle, significantly improving memory access efficiency and the Instructions Per Cycle (IPC) metric. In contrast, EVA0 lacks the early write capability, necessitating sequential data transfer and write operations within the GTP pulse width. This limitation requires a longer Self Timing Pulse (STP) width to ensure reliable write operations, resulting in a timing disparity between the two modes. The architectural differences pose a design challenge in achieving robust performance across both modes while adhering to stringent system timing constraints.

While EVA1 benefits from inherent timing margins provided by early write, EVA0 suffers from inadequate write margins, creating a critical challenge for reliable operation at higher clock frequencies. This mismatch between the circuit's timing behavior and EVA=0's requirements poses a significant design hurdle in modern high-performance systems.

To address this challenge, advantageously, inventive aspects introduce a pulse extension mechanism specifically for EVA=0 to ensure sufficient write margin while maintaining compatibility with higher clock frequency requirements. This solution includes additional control delay circuitry and a fixed delay element, such as an Extra Margin Adjustment for Write (EMAW) delay chain, which selectively extends the STP during EVA=0 write operations. This approach dynamically adjusts the circuit's timing without impacting the overall clock period.

The proposed schemes and techniques also repurpose the EVA static pin, traditionally used for mode selection, as part of the control circuitry. In various implementations, the EVA pin dynamically enables or disables pulse extension based on the operating mode. In EVA=1, the pulse extension is unnecessary due to the inherent timing margin provided by early write, allowing both read and write operations to complete within the clock period. In EVA=0, the EVA pin combines with a global write enable signal (GWEN) through a logic circuit (e.g., a multiplexer or OR/AND gates) to selectively extend the pulse for write operations. This targeted extension ensures successful single write operations in EVA=0 without compromising read operations or introducing timing penalties. Additionally, as a further advantage, the solution avoids modifications to EVA=1 circuitry, minimizing design complexity and maintaining compatibility with existing implementations. By selectively applying the pulse extension, the same clock frequency can be maintained across both modes, preserving overall system performance and reliability.

Certain definitions have been provided herein for reference. The global timing pulse signal (GTP) is an internally generated clock signal that provides a uniform time reference for read and write memory operations across the chip, ensuring synchronized and coherent functionality during both functional and test modes. The clock signal (CLK) is a periodic timing signal used to synchronize operations across a circuit, providing a reference for the sequential execution of tasks such as data transfers, computations, and control signal generation in digital systems. A global write enable signal (e.g., GWEN) is a binary control signal used in circuit design to determine whether a write operation should occur for an entire word or memory location. GWEN operates at the word or block level, enabling or disabling the writing of data to the addressed memory cell or register. For example, GWEN is active-low for write operations, and active-high for read operations.

In this context, Self-Timed Pulse (STP) refers to a timing signal generated internally within the circuit that governs the duration of specific operations, such as read or write, in a memory or CPU system. The STP is dynamically adjusted based on the operation mode (e.g., EVA=0 or EVA=1) to ensure proper synchronization and sufficient timing margins. In EVA=1, the STP aligns with the global timing pulse (GTP) and leverages early write techniques to overlap read and write operations within the clock cycle. In EVA=0, according to inventive aspects, the STP may be extended using additional control logic and delay elements to provide the necessary write margin for successful operation under the stricter timing constraints of a single operation. The STP plays a critical role in achieving robust performance and meeting target frequencies, particularly under high-speed CPU requirements.

The Eviction and Allocation (EVA) static pin is a control signal used to enable the Eviction and Allocation (EVA) feature in memory systems, which supports both read and write operations. This pin determines the operational mode of the system as follows: 1) EVA=1 (Dual-operation mode): Enables sequential read and write operations within a single clock cycle from the same address location. This mode leverages early write techniques, allowing the write operation to begin before the read operation fully completes, thereby optimizing timing efficiency and ensuring both operations complete within the clock cycle. 2) EVA=0 (Single-operation mode): Allows only a read or a write operation to occur within the clock cycle. In this mode, pulse extension is applied selectively during write operations to ensure sufficient timing margin and robust performance. Although static in nature, the EVA pin dynamically configures the circuit's behavior to adapt to the operational mode, ensuring reliable performance and maintaining high frequency operation under stringent timing constraints.

Nyr (Read Enable Signal): A signal that enables the read operation. The falling edge of the wordline enable signal triggers the closure of the read operation, and the rise of nyr indicates the end of the read process. Yw (Write Enable Signal): A signal that initiates the write operation. The write process begins with the rise of yw, signaling the transition to the write phase. Wordline enable is a signal that controls the activation of the wordline. The falling edge signifies the end of the read operation, allowing subsequent operations, such as write, to proceed. Wclk (Write Clock):
A clock signal used to transfer data to the bitlines. It ensures complementary data is generated, leveraging the rising edge of the clock signal in a double-clock configuration. This complementary data is necessary for proper write operations.

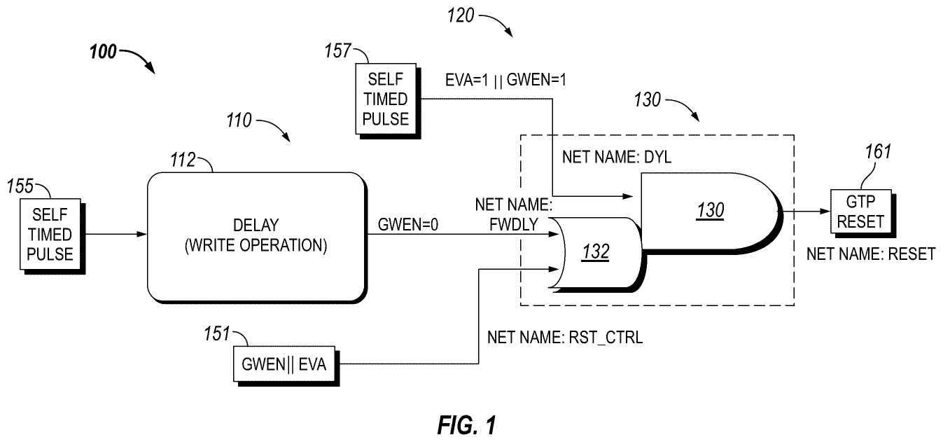

Referring to FIG. 1, an example circuit arrangement 100 (i.e., a GTP reset delay and control circuit) according to example implementations is shown. The circuit 100 can include a first circuit path 110 comprising: a delay element 112, a second circuit path 120, and a multiplexer 130. In various cases, the multiplexer 130 is configured to select between respective first and second GTP signals 155, 157 of the first circuit path 110 and the second circuit path 120 based on a control signal 151 (i.e., EVA static pin, dynamic pulse control). Advantageously, during a reset edge of a first read operation, the circuit 100 is configured to combine the EVA pin 151 is combine (e.g., “mix”) with the write enable signal (GWEN) to extend the pulse width for the write operation in EVA=0, ensuring a successful operation while maintaining frequency constraints.

In certain implementations, as shown, the multiplexer 130 is configured to output a GTP reset signal 161, where the GTP reset signal 161 corresponds to either the first GTP signal 155 (i.e., FWDLY) or the second GTP signal 157 (i.e., DYL). As illustrated, the first and second GTP signals 155, 157 correspond to respective first and second internal self-timed-pulse (STP) signals 155, 157. In various cases, the first GTP signal 155 is a delayed version of the second GTP signal 157. Also, in such cases, the first GTP signal 155 corresponds to a first pulse width and the second GTP signal 157 corresponds to a second pulse width, where the first pulse width is a lesser or substantially same duration in comparison to the second pulse width.

In some implementations, the delay element 112 can include an extra margin adjustment write (EMAW) delay chain circuitry. In some cases, the multiplexer 130 includes an OR gate 132 and an AND gate 134, where an output of the OR gate 132 corresponds to a first input of the AND gate 134; and the output of the AND gate 134 corresponds to a reset pulse (e.g., GTP reset signal 161). In such cases, a first input of the OR gate 132 corresponds to the control signal 151; and a second input of the OR gate 132 corresponds to an output of the first circuit path 110 (e.g., GTP signal 155; EVA=0 scenario). Also, in such cases, a second input of the AND gate 134 corresponds to an output of the second circuit path 120 (e.g., GTP signal 157; EVA=1 scenario).

In various cases, the first circuit path 120 corresponds to a propagation of a first internal self-timed-pulse (STP) signal 155, and the second circuit path corresponds to a propagation of a second internal self-timed-pulse (STP) signal 157. In such cases, the first internal self-timed-pulse (STP) signal 155 corresponds to a GTP pulse width of a read operation or a write operation, and the second internal self-timed-pulse (STP) signal 157 corresponds to a GTP pulse width of a write operation, for example.

Advantageously, as described with reference to example operations, for the EVA1 case, the circuit 100 is configured to reset GTP by the internal self-timed pulse. In addition, for the EVA0 case, to enable and/or improve writability, extra-EMAW delay chains can be added to the internal self-timed pulse.

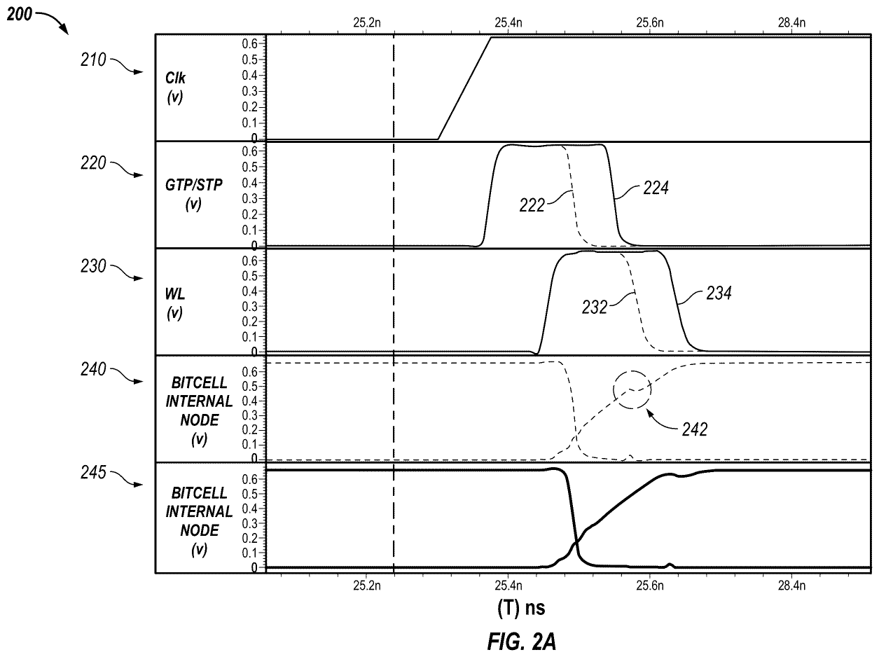

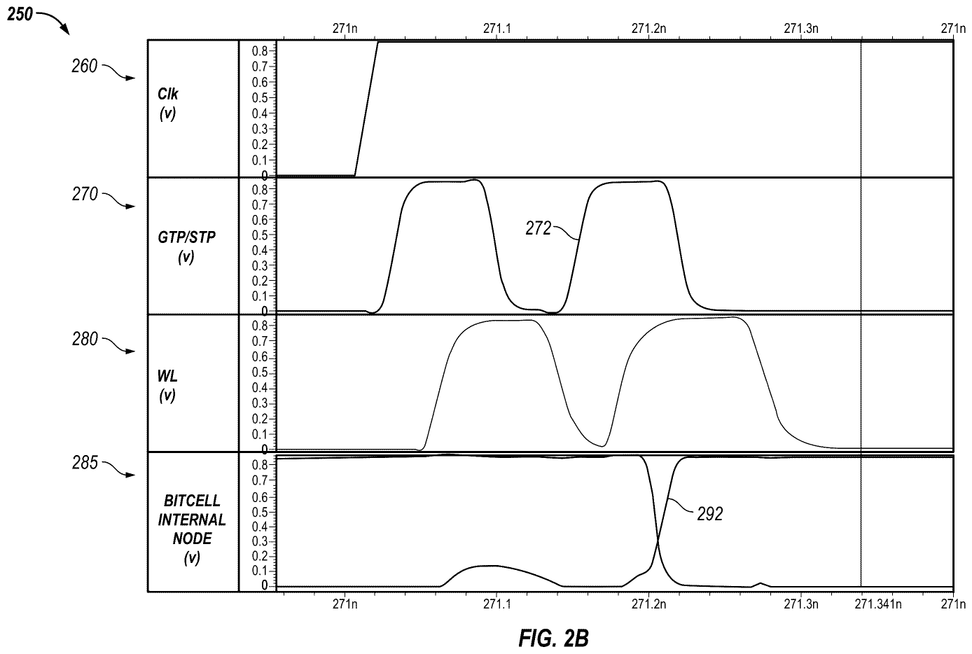

Referring to FIG. 2A, graph set 200 illustrates example waveform timing diagrams 210, 220, 230, 240, and 245 discussed with reference to the inventive GTP reset circuitry 100 in FIG. 1 according to example implementations. Each of the timing diagrams illustrate voltage (V) (e.g., from digital high (“1” or “0.7”) to digital low (“0”)) as a function of time (e.g., ns) for the following signal waveforms: CLK (210), GTP /TP (220), WL (230), and voltage at an internal node of the bitcell before (240) and after (245) the delay provided by the inventive circuit 100 operation. As one example, timing diagram 210 illustrates the timing diagram for the external clock (CLK). Timing diagram 220 illustrates the timing diagram for self-timed pulse (STP)/global timing pulse (GTP) in the EVA=0 scenario for the single write operation. As shown, the waveform 222 represents the baseline STP/GTP signal, while the waveform 224 represents the STP/GTP signal that is extended by delay introduced the inventive circuit 100. In addition, timing diagram 230 illustrates the waveform for a corresponding wordline activation signal (WL). The waveform 232 represents the baseline WL activation signal, while the waveform 234 represents the WL activation signal that is extended by the delay introduced by the inventive circuit 100.

Moreover, timing diagram 240 illustrates the EVA=0 scenario baseline without delay scenario. As shown, illustrating one underlying problem, the rising edge of the internal node in the bitcell exhibits a “kink” (242) indicating an incomplete charging prior to the “close” of the wordline. As may be appreciated, such a kink results in a violation of the write operation, as the signal would fail to reach 70-80% of the full rail voltage before reset. In comparison, the timing diagram 245 illustrates the EVA=0 scenario with the delay extension, resulting in no “kink”. Advantageously, for example, as shown in timing diagram 245, the internal node reaches the full rail voltage within the pulse width; thereby achieving a successful write operation. As would be appreciated, the inventive extended pulse facilitates faster, steeper transitions, allowing for the bitcell to robustly “flip” its stored data (e.g., from “0” to “1”).

In summary, such an inventive approach enhances the robustness and reliability of single write operations in EVA=0 while maintaining the frequency target. By introducing a delay that safeguards data flipping without compromising system performance, the design achieves greater stability and sharper signal integrity. The improved pulse margin not only ensures successful operations but also boosts overall yield, resulting in a more resilient system optimized for single-operation scenarios.

Referring to FIG. 2B, graph set 250 example waveform timing diagrams 260, 270, 280, and 285 are discussed with reference to the inventive GTP reset circuitry 100 in FIG. 1 according to example implementations. Each of the timing diagrams illustrate voltage (V) (e.g., from digital high (“1” or ‘0.7”) to digital low (“0”)) as a function of time (e.g., ns) for the following signal waveforms: CLK (260), GTP/STP (270), WL (280), and voltage at an internal node of the bitcell provided by the inventive circuit 100 operation. As one example, timing diagram 260 illustrates the timing diagram for the external clock (CLK). Timing diagram 270 illustrates the timing diagram for self-timed pulse (STP)/global timing pulse (GTP) in the EVA=1 scenario for the dual read and write operation. As shown, the waveform 272 represents STP/GTP signal. In addition, timing diagram 280 illustrates the waveform for a corresponding wordline activation signal (WL). The example waveform 285 represents the WL activation signal utilizing the early write feature. For example, during the early write feature in the EVA=1 mode, the write operation can begin early and overlap with the end of the read operation; thereby, effectively “squeezing” both operation in the same clock cycle (e.g., 250 picoseconds). Accordingly, the initial pulse width (e.g., as non-extended) is sufficient in EVA=1 because the early write creates a “healthy” margin for the write operation. Also, as shown, the rising edge of the internal node in the bitcell exhibits no “kink” (292) indicating a complete charging prior to the close of the wordline. Advantageously, while included in the circuit 100, the write GTP pulse width operation in EVA=1 mode would not change. For example, the circuit path 120 remains the same before and after such a design update.

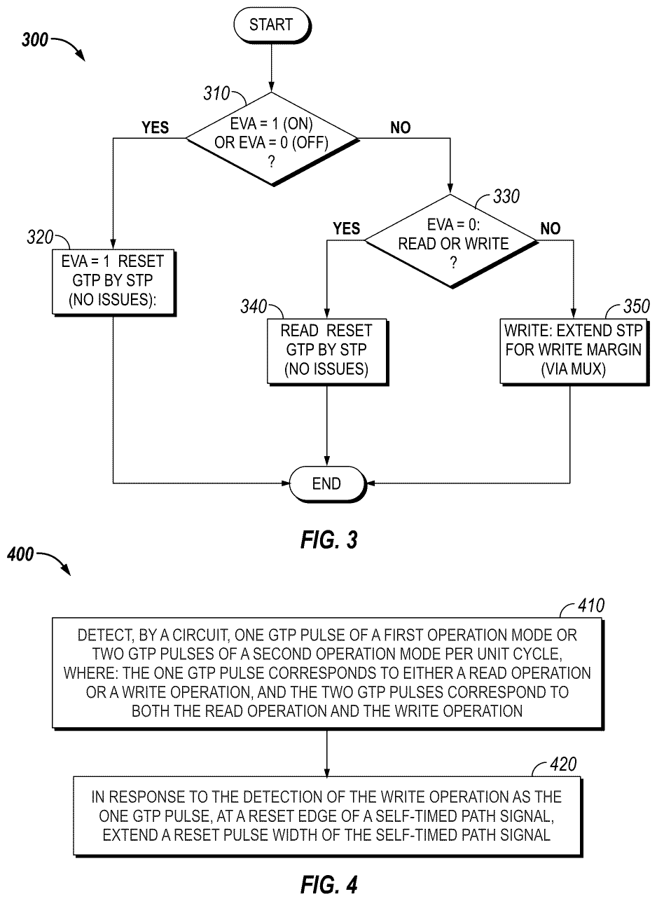

FIG. 3 is an example flow diagram 300 is shown in accordance with certain implementations. As illustrated, the flow diagram 300 represents an example order of system operation. In various implementations, an inventive system (e.g., inventive scheme involving the circuit 100 implemented in accordance with example computer 600) provides the capacity to dynamically adjust pulse width and for selective write pulse extension for a write operation in EVA=0 mode. For instance, the system has the capability to introduce a delay for the self-timed pulse.

At Step 310, the system (e.g., circuit 100, computer 600) detects whether one GTP pulse in a first operation mode (e.g., EVA=0 condition) or two GTP pulses in a second operation mode (e.g., EVA=1 condition) are transmitted per unit clock cycle (see also FIG. 4). If it is determined that the EVA feature is “ON” (e.g., EVA=1), the system moves to Step 320 where the system resets GTP by the internal STP. As may be appreciated, there would be no issue in this scenario due to implementation of early write. If it is determined that the EVA feature is “OFF” (e.g., EVA=0), the system moves to Step 330 where the system determines whether the one GTP pulse corresponds to either a read operation or a write operation. At Step 340, if the one GTP pulse corresponds to the read operation, the system proceeds to reset GTP by the internal GTP.

However, at Step 350, if the single GTP pulse corresponds to a write operation, upon the arrival of a clock signal (e.g., as shown in waveform timing diagram 210 in FIG. 2A), and during the reset edge of GTP/STP signal only (e.g., as shown in waveform timing diagram 220), the GTP/STP signal can be extended to increase write margin. In example implementations, such an extension can be achieved by “mixing” (e.g., combining) by a multiplexer, a write enable signal (e.g., GWEN; corresponding to a delayed STP) and an EVA pin. By doing so, advantageously, the reset edge (i.e., the falling edge) of the GTP/STP signal can be extended, while no change would occur to the signal's rising edge.

Referring to FIG. 4, a flowchart of an example operational method 400 (i.e., procedure) is shown. Advantageously, in various implementations, the method 400 describes the capability for dynamic pulse width adjustment, e.g., selective write pulse adjustment during write operation in the EVA=0 operational mode. The method 400 may be implemented with reference to implementation as shown with reference to FIGS. 1-3.

At block 410, the example method 400 includes: detecting, by a circuit, one GTP pulse of a first operational mode or two GTP pulses of a second operational mode per unit cycle, where: the one GTP pulse corresponds to either a read operation or a write operation, and the two GTP pulses correspond to both the read operation and the write operation. For instance, as described with reference to FIGS. 1-3 (e.g., Step 310 of FIG. 3), the circuit 100 (in conjunction with the computer 600) is configured to detect one GTP pulse of a first operational mode (e.g., EVA=0) or two GTP pulses of a second operational mode (e.g., EVA=1) per unit cycle.

At block 420, the example method 400 includes: in response to the detection of the write operation as the one GTP pulse, at a reset edge of a self-timed path signal (STP), extending a reset pulse width of the self-timed path signal. For instance, as described with reference to FIGS. 1-3 (e.g., Step 350 of FIG. 3), in response to the detection of the write operation as the one GTP pulse, and upon an arrival of a clock signal, at a reset edge of a self-time path signal (STP), a reset pulse width of the self-time path signal can be extended.

In certain cases, the method 400 further includes that the self-timed path signal is extended via one or more delay elements of a selected circuit path of the circuit; and that the self-timed path signal corresponds to the one GTP pulse.

In some implementations, the method 400 includes: in response to the detection of the two GTP pulses or in response to the detection of the read operation as the one GTP pulse, transmitting a non-extended version of the self-time path signal as a GTP pulse reset signal. Moreover, in such implementations, the GTP pulse reset signal would correspond to the one GTP pulse in the first operation mode (EVA=0) or a second of the two GTP pulses in the second operation mode (EVA=1).

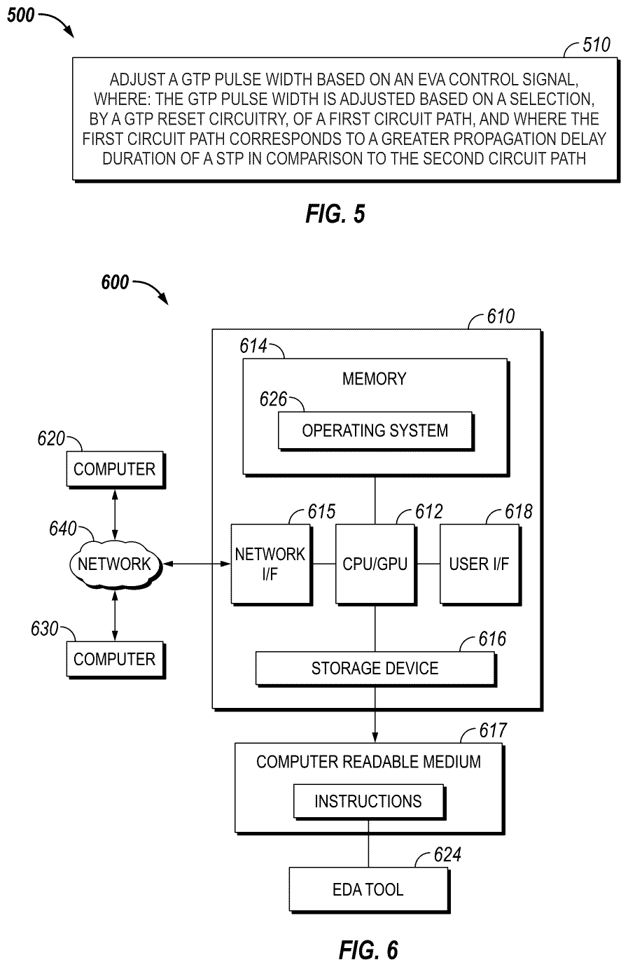

Referring to FIG. 5, a flowchart of an example operational method 500 (i.e., procedure) is shown. Advantageously, in various implementations, the method 500 describes the capability to provide an extended (e.g., “healthy”; robust) write margin in the EVA=0 operational mode. The method 500 may be implemented with reference to implementation as shown with reference to FIGS. 1, 2A and 3.

At block 510, the example method 500 includes: adjusting a GTP pulse width based on an eviction-and-allocation (EVA) control signal, where: the GTP pulse width is adjusted based on a selection, by a GTP reset circuitry, of a first circuit path, and wherein: the first circuit path corresponds to a greater propagation delay duration of a self-timed pulse (STP) in comparison to the second circuit path. For example, with reference to FIGS. 1, 2A, and 3, the method 500 includes: (selectively) adjusting (e.g., modulating) a GTP pulse width (e.g., the pulse width difference between waveforms 224 and 222 in FIG. 2A) based on an eviction-and-allocation (EVA) control signal (assertion) 151, where: the GTP pulse width is adjusted based on a selection, by a multiplexer 130 of a GTP reset circuitry 100, of a first circuit path 110, and where: the first circuit path 110 corresponds to a greater propagation delay duration of a self-timed pulse (STP) in comparison to a second circuit path 120.

In some cases, the method 500 includes that the GTP corresponds to the STP. In certain instances, the method 500 includes in response to the section of the first circuit path (e.g., EVA=0), during a reset edge of a clock signal (e.g., only), the GTP reset circuitry is configured to combine (e.g., “mix”) the EVA control signal and a write enable signal (GWEN) so as to extend the GTP pulse width.

In certain scenarios, a reset output of the reset circuitry corresponds to a first GTP pulse width or a second GTP pulse width; and the first GTP pulse width comprises a pulse width of a lesser or substantially same duration than the second GTP pulse width. In some instances, the first circuit path corresponds to an EVA assertion at a digital low (OFF), and the second circuit path corresponds to an EVA assertion at a digital high (ON). In various cases, the EVA assertion at the digital low corresponds to a single (internal) GTP pulse per clock cycle; and the EVA assertion at the digital high corresponds to first and second (internal) GTP pulses per clock cycle. In some cases, the first circuit path corresponds to a propagation of a first self-timed pulse, and the second circuit path corresponds to a propagation of a second self-timed pulse, wherein the first self-timed pulse comprises a delay duration (e.g., corresponding to an increased pulse-width).

FIG. 6 illustrates example hardware components in the computer system 600 that may be used to facilitate and generate the inventive circuit design/memory architecture output. In certain implementations, the example computer system 600 (e.g., networked computer system and/or server) may include EDA tool 624 to execute software based on the procedure as described with reference to the methods as described herein. For example, FIG. 6 illustrates example hardware components in the computer system 600 that may be used for dynamic pulse width adjustment, e.g., selective write pulse extension during a write operation in EVA=0 mode. In certain implementations, the EDA too 624 may be included as a feature of an existing compiler software program. In certain implementations, an EDA (Electronic Design Automation) tool 624 would automate signal detection and control logic configuration for the schemes and techniques as described herein (e.g., with reference to the circuit 100 illustrated in FIG. 1 and the flow diagram 300 illustrated in FIG. 3).

In various cases, the EDA tool 624 is configured to enact the inventive circuit design by automating the synthesis, simulation, verification, and optimization of the memory control logic to implement the described functionality. The tool incorporates dynamic pulse width adjustment and selective write pulse extension for write operations in EVA=0 mode, ensuring robust operation while maintaining system performance. The tool begins by detecting whether one Global Timing Pulse (GTP) or two GTPs are transmitted per clock cycle, corresponding to EVA=0 and EVA=1 modes, respectively. If a single GTP pulse is detected, the tool determines whether it represents a read or write operation. For write operations in EVA=0 mode, the tool introduces a delay by extending the reset edge of the self-timed path (STP) signal to increase write margin. This extension is achieved by dynamically combining a write enable signal (e.g., GWEN) and an EVA pin using a multiplexer, ensuring the rising edge of the GTP/STP signal remains unchanged.

In such cases, the EDA tool 624 synthesizes custom circuit modules to implement this logic, including STP delay elements, multiplexers, and synchronization elements, ensuring alignment with memory clock cycles and operational timing. Functional simulations validate the design under various scenarios, such as read/write operations with single GTP pulses or two GTP pulses, ensuring reliable operation and power-saving capabilities. The tool 624 also enables the configuration of EVA control signals for selecting circuit paths with different propagation delay durations to modulate GTP pulse widths dynamically.

In addition, the EDA tool 624 performs critical path analysis and timing optimization to ensure fast GTP pulse detection and reliable signal transitions, minimizing delays while maintaining data integrity. Physical design steps focus on optimizing the layout to reduce area and routing overhead while isolating sensitive signals to prevent interference. Power analysis quantifies dynamic power reductions achieved through selective pulse extension, ensuring compliance with power, performance, and area (PPA) goals. Formal verification confirms the design's equivalence to specifications, generating test vectors for post-silicon validation. The finalized design integrates seamlessly into larger processing units (e.g., CPUs GPUs, etc.) or system-on-chip (SoC) architectures, offering runtime tunability for dynamic workload adjustments. This comprehensive workflow enables efficient and scalable implementation of the inventive memory architecture, balancing high performance and power efficiency for advanced computing systems.

The procedures (e.g., 400, 500), for example, may be stored as program instructions as instructions 617 in the computer readable medium of the storage device 616 (or alternatively, in memory 614) that may be executed by the computer 610, or networked computers 620, 630, other networked electronic devices (not shown) or a combination thereof. In certain implementations, each of the computers 610, 620, 630 may be any type of computer, computer system, or other programmable electronic device. Further, each of the computers 610, 620, 630 may be implemented using one or more networked computers, e.g., in a cluster or other distributed computing system.

In certain implementations, the system 600 may be used with semiconductor integrated circuit (IC) designs that contain all standard cells, all blocks or a mixture of standard cells and blocks. In a particular example implementation, the system 600 may include in its database structures: a collection of cell libraries, one or more technology files, a plurality of cell library format files, a set of top design format files, one or more Open Artwork System Interchange Standard (OASIS/OASIS.MASK) files, and/or at least one EDIF file. The database of the system 600 may be stored in one or more of memory 614 or storage devices 616 of computer 610 or in networked computers 620, 630.

In one implementation, the computer 600 includes a central processing unit (CPU) 612 (or graphics processing unit (GPU) or neural processing unit (NPU) in certain implementations) having at least one hardware-based processor coupled to a memory 614. The memory 614 may represent random access memory (RAM) devices of main storage of the computer 610, supplemental levels of memory (e.g., cache memories, non-volatile or backup memories (e.g., programmable or flash memories)), read-only memories, or combinations thereof. In addition to the memory 614, the computer system 600 may include other memory located elsewhere in the computer 610, such as cache memory in the CPU 612, as well as any storage capacity used as a virtual memory (e.g., as stored on a storage device 616 or on another computer coupled to the computer 610).

The computer 610 may further be configured to communicate information externally. To interface with a user or operator (e.g., a circuit design engineer), the computer 610 may include a user interface (I/F) 618 incorporating one or more user input devices (e.g., a keyboard, a mouse, a touchpad, and/or a microphone, among others) and a display (e.g., a monitor, a liquid crystal display (LCD) panel, light emitting diode (LED), display panel, and/or a speaker, among others). In other examples, user input may be received via another computer or terminal. Furthermore, the computer 610 may include a network interface (I/F) 615 which may be coupled to one or more networks 640 (e.g., a wireless network) to enable communication of information with other computers and electronic devices. The computer 560 may include analog and/or digital interfaces between the CPU 612 and each of the components 614, 615, 616, and 618. Further, other non-limiting hardware environments may be used within the context of example implementations.

The computer 610 may operate under the control of an operating system 626 and may execute or otherwise rely upon various computer software applications, components, programs, objects, modules, data structures, etc. (such as the programs associated with the procedure 400 and related software). The operating system 628 may be stored in the memory 614. Operating systems include, but are not limited to, UNIX® (a registered trademark of The Open Group), Linux® (a registered trademark of Linus Torvalds), Windows® (a registered trademark of Microsoft Corporation, Redmond, WA, United States), AIX® (a registered trademark of International Business Machines (IBM) Corp., Armonk, NY, United States) i5/OS® (a registered trademark of IBM Corp.), and others as will occur to those of skill in the art. The operating system 626 in the example of FIG. 6 is shown in the memory 614, but components of the aforementioned software may also, or in addition, be stored at non-volatile memory (e.g., on storage device 616) and/or the non-volatile memory (not shown). Moreover, various applications, components, programs, objects, modules, etc. may also execute on one or more processors in another computer coupled to the computer 610 via the network 640 (e.g., in a distributed or client-server computing environment) where the processing to implement the functions of a computer program may be allocated to multiple computers 620, 630 over the network 640. In example implementations, circuit related diagrams have been provided in FIG. 1-6, whose redundant description has not been duplicated in the related description of analogous circuit related diagrams. It is expressly incorporated that the same diagrams with identical symbols and/or reference numerals are included in each of embodiments based on its corresponding figure(s).

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define an HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally, or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively, or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively, or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

Computer-readable program instructions described herein can be downloaded to respective computing/processing devices from a computer-readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer-readable program instructions from the network and forwards the computer-readable program instructions for storage in a computer-readable storage medium within the respective computing/processing device.

Computer-readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and procedural programming languages, such as the “C” programming language or similar programming languages. The computer-readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some implementations, electronic circuitry including, for example, programmable logic circuitry or programmable logic arrays (PLA) may execute the computer-readable program instructions by utilizing state information of the computer-readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer-readable program instructions.

These computer-readable program instructions may be provided to a processor of a general-purpose computer, a special purpose computer, or other programmable data processing apparatus to produce a machine, where such instructions may execute via the processor of the computer or other programmable data processing apparatus. The machine is an example of means for implementing the functions/acts specified in the flowchart and/or block diagrams. The computer-readable program instructions may also be stored in a computer-readable storage medium that can direct a computer, a programmable data processing apparatus, and/or other devices to function in a particular manner, such that the computer-readable storage medium having instructions stored therein comprises an article of manufacture including instructions which implement aspects of the functions/acts specified in the flowchart and/or block diagrams.

The computer-readable program instructions may also be loaded onto a computer, other programmable data processing apparatus, or other device to cause a series of operational steps to be performed on the computer, other programmable apparatus or other device to perform a computer implemented process, such that the instructions which execute on the computer, other programmable apparatus, or other device implement the functions/acts specified in the flowchart and/or block diagrams.

The flowchart and block diagrams in the Figures illustrate the architecture, functionality, and operation of possible implementations of systems, methods, and computer program products according to various implementations of the present disclosure. In this regard, each block in the flowchart or block diagrams may represent a module, segment, or portion of instructions, which comprises one or more executable instructions for implementing the specified logical function(s). In some alternative implementations, the functions noted in a block in a diagram may occur out of the order noted in the figures. For example, two blocks shown in succession may be executed substantially concurrently, or the blocks may sometimes be executed in the reverse order, depending upon the functionality involved. It will also be noted that each block of the block diagrams and/or flowcharts, and combinations of blocks in the block diagrams and/or flowcharts, can be implemented by special purpose hardware-based systems that perform the specified functions or acts or carry out combinations of special purpose hardware and computer instructions.

In the following description, numerous specific details are set forth to provide a thorough understanding of the disclosed concepts, which may be practiced without some or all of these particulars. In other instances, details of known devices and/or processes have been omitted to avoid unnecessarily obscuring the disclosure. While some concepts will be described in conjunction with specific examples, it will be understood that these examples are not intended to be limiting.

Unless otherwise indicated, the terms “first”, “second”, etc. are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item.

Reference herein to “one example” means that one or more feature, structure, or characteristic described in connection with the example is included in at least one implementation. The phrase “one example” in various places in the specification may or may not be referring to the same example.

Illustrative, non-exhaustive examples, which may or may not be claimed, of the subject matter according to the present disclosure are provided below. Different examples of the device(s) and method(s) disclosed herein include a variety of components, features, and functionalities. It should be understood that the various examples of the device(s) and method(s) disclosed herein may include any of the components, features, and functionalities of any of the other examples of the device(s) and method(s) disclosed herein in any combination, and all such possibilities are intended to be within the scope of the present disclosure. Many modifications of examples set forth herein will come to mind to one skilled in the art to which the present disclosure pertains having the benefit of the teachings presented in the foregoing descriptions and the associated drawings.

Therefore, it is to be understood that the present disclosure is not to be limited to the specific examples illustrated and that modifications and other examples are intended to be included within the scope of the appended claims. Moreover, although the foregoing description and the associated drawings describe examples of the present disclosure in the context of certain illustrative combinations of elements and/or functions, it should be appreciated that different combinations of elements and/or functions may be provided by alternative implementations without departing from the scope of the appended claims. Accordingly, parenthetical reference numerals in the appended claims are presented for illustrative purposes only and are not intended to limit the scope of the claimed subject matter to the specific examples provided in the present disclosure.

What is claimed is:

1. A circuit for selective write pulse extension comprising:
a first circuit path comprising: a delay element;
a second circuit path; and
a multiplexer configured to select between respective first and second global timing pulse (GTP) signals of the first circuit path and the second circuit path based on a control signal.

2. The circuit of claim 1, wherein:
the multiplexer is configured to output a GTP reset signal, wherein
the GTP reset signal corresponds to either the first GTP signal or the second GTP signal.

3. The circuit of claim 1, wherein the first and the second GTP signals correspond to respective first and second internal self-timed pulse (STP) signals.

4. The circuit of claim 1, wherein:
the first GTP signal is a delayed version of the second GTP signal; and
the first GTP signal corresponds to a first pulse width and the second GTP signal corresponds to a second pulse width.

5. The circuit of claim 1, wherein:
the delay element comprises delay chain circuitry.

6. The circuit of claim 1, wherein the multiplexer comprises:
an OR gate; and
an AND gate, wherein:
an output of the OR gate corresponds to a first input of the AND gate; and
the output of the AND gate corresponds to a reset pulse.

7. The circuit of claim 6, wherein:
a first input of the OR gate corresponds to the control signal; and
a second input of the OR gate corresponds to an output of the first circuit path.

8. The circuit of claim 6, wherein:
a second input of the AND gate corresponds to an output of the second circuit path.

9. The circuit of claim 1, wherein:
the first circuit path corresponds to a propagation of a first internal self-timed-pulse (STP) signal, and
the second circuit path corresponds to a propagation of a second internal self-timed-pulse (STP) signal.

10. The circuit of claim 9, wherein:
the first internal self-timed-pulse (STP) signal corresponds to a GTP pulse width of a read operation or a write operation, and
the second internal self-timed-pulse (STP) signal corresponds to a GTP pulse width of a write operation.

11. A method for selective write pulse extension comprising:
detecting, by a circuit, one GTP pulse of a first operation mode or two GTP pulses of a second operation mode per unit cycle, wherein:
the one GTP pulse corresponds to either a read operation or a write operation, and
the two GTP pulses correspond to both the read operation and the write operation; and
in response to the detection of the write operation as the one GTP pulse, at a reset edge of a self-timed path signal, extending a reset pulse width of the self-timed path signal.

12. The method of claim 11, wherein:
the self-timed path signal is extended via one or more delay elements of a selected circuit path of the circuit; and
the self-timed path signal corresponds to the one GTP pulse.

13. The method of claim 11, further comprising:
in response to the detection of the two GTP pulses or in response to the detection of the read operation as the one GTP pulse, transmitting a non-extended version of the self-timed path signal as a GTP pulse reset signal, wherein:
the GTP pulse reset signal corresponds to the one GTP pulse in the first operation mode or a second of the two GTP pulses in the second operation mode.

14. A method for selective write pulse extension comprising:
adjusting a GTP pulse width based on an eviction-and-allocation (EVA) control signal, wherein:
the GTP pulse width is adjusted based on a selection, by a GTP reset circuitry, of a first circuit path, and wherein:
the first circuit path corresponds to a greater propagation delay duration of a self-timed pulse (STP) in comparison to a second circuit path.

15. The method of claim 14, wherein the GTP corresponds to the STP.

16. The method of claim 14, wherein:
in response to the section of the first circuit path,
during a reset edge of a clock signal, the GTP reset circuitry is configured to combine the EVA control signal and a write enable signal so as to extend the GTP pulse width.

17. The method of claim 14, wherein:
a reset output of the reset circuitry corresponds to a first GTP pulse width or a second GTP pulse width; and
the first GTP pulse width comprises a pulse width lesser than or substantially same duration as the second GTP pulse width.

18. The method of claim 14, wherein:
the first circuit path corresponds to an EVA assertion at a digital low; and
the second circuit path corresponds to an EVA assertion at a digital high.

19. The method of claim 18, wherein:
the EVA assertion at the digital low corresponds to a single GTP pulse per clock cycle; and
the EVA assertion at the digital high corresponds to first and second GTP pulses per clock cycle.

20. The method of claim 14, wherein:
the first circuit path corresponds to a propagation of a first self-timed pulse; and
the second circuit path corresponds to a propagation of a second self-timed pulse, wherein the first self-timed pulse comprises a delay duration.
